(19) United States
(12) Patent Application Publication
(10) Pub. No.: US 2025/0113558 A1
(43) Pub. Date: Apr. 3, 2025

(54) SEMICONDUCTOR DEVICE WITH SELF-ALIGNED NITRIDE FOR POWER ISOLATION

(71) Applicant: Texas Instruments Incorporated, Dallas, TX (US)

(72) Inventors: Gowrisankar Damarla, Lehi, UT (US); Robert Cassel, Lehi, UT (US); Zachary Katz, Lehi, UT (US); Ryan Rust, Lehi, UT (US)

(21) Appl. No.: 18/374,517

(22) Filed: Sep. 28, 2023

(51) Int. Cl. H01L 29/06; H01L 29/40; H01L 29/423; H01L 29/66; H01L 29/78

(52) U.S. Cl. CPC H10D 62/115; H10D 30/0281; H10D 30/65; H10D 64/01; H10D 64/516

(57) ABSTRACT

A method of forming an integrated circuit includes forming a first trench that extends into the semiconductor substrate. A silicon nitride layer is deposited over the semiconductor substrate. The silicon nitride layer extends into the first trench. A second trench is formed that extends through the silicon nitride layer into the semiconductor substrate. The second trench is spaced apart from the first trench. An oxide layer is formed that fills the second trench. The silicon nitride layer outside the first trench is removed.

### RELATED APPLICATION

The present application is related to co-owned U.S. patent application Ser. No. 18/361,880, entitled “Semiconductor Device with a High K Field Relief Dielectric Structure,” filed Jul. 30 2023, which is hereby incorporated by reference in its entirety herein.

### BACKGROUND

Semiconductor components are being continually improved to reliably operate with smaller feature sizes. Fabricating semiconductor devices that have increasingly higher performance while meeting reliability specifications is challenging.

### SUMMARY

This summary is provided to introduce a brief selection of disclosed concepts in a simplified form that are further described below in the detailed description including the drawings provided. This summary is not intended to limit the claimed subject matter's scope.

In a first example, a method of forming an integrated circuit includes forming a power isolation trench that extends into the semiconductor substrate. A silicon nitride layer is deposited over the semiconductor substrate. The silicon nitride layer extends into the power isolation trench. A shallow isolation trench is formed that extends through the silicon nitride layer into the semiconductor substrate. The shallow isolation trench is spaced apart from the power isolation trench. An oxide layer is formed that fills the shallow isolation trench. The silicon nitride layer outside the power isolation trench is removed.

In a second example, a semiconductor device includes a semiconductor material of a substrate, a first trench, and a second trench. The semiconductor material includes a body region having a first conductivity type and a drain drift region having a second conductivity type. The first trench extends into the body region and is at least partially filled by a dielectric material. The second trench extends into the drain drift region and is at least partially filed by a silicon nitride layer. The silicon nitride layer extends above a top surface of the drain drift region. The silicon nitride layer forms a projected trench above the second trench. The projected trench is at least partially filled with the dielectric material.

In a third example, a semiconductor device includes a semiconductor material of a substrate, a first trench, and a second trench. The semiconductor material includes a body region having a first conductivity type and a drain drift region having a second conductivity type. The first trench extends into the body region and is at least partially filled by a dielectric material. The second trench extends into the drain drift region and is at least partially filled by a silicon nitride layer. The silicon nitride layer has a top surface that is coplanar with a top surface of the drain drift region.

### BRIEF DESCRIPTION OF THE DRAWINGS

FIGS. 1 and 2 are cross sections of an example microelectronic device including a transistor in various stages of formation.

FIGS. 3A through 3C are cross sections of two separate portions of the example microelectronic device of FIGS. 1 and 2, in which are shown a power isolation region and a shallow trench isolation region of the transistor, in successive stages of formation.

FIGS. 4A through 4E are cross sections of the microelectronic device of FIGS. 1 and 2, in which are shown a power isolation region and a shallow trench isolation region in successive stages of formation according to a first process flow. The first process flow can be executed subsequent to the respective process flows described with reference to FIG. 2 or FIGS. 3A through 3C.

FIGS. 5A through 5F are cross sections of the microelectronic device of FIGS. 1 and 2, in which are shown a power isolation region and a shallow trench isolation region in successive stages of formation according to a second process flow. The second process flow can be executed subsequent to the respective process flows described with reference to FIG. 2 or FIGS. 3A through 3C.

### DETAILED DESCRIPTION

The present disclosure is described with reference to the attached figures. The same reference numbers or other reference designators are used in the drawings to designate the same or similar (functionally and/or structurally) features. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the examples illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present disclosure is illustrated by examples directed to active devices, it is not intended that these illustrations be a limitation on the scope or applicability of the present disclosure. It is not intended that the active devices of the present disclosure be limited to the physical structures illustrated. These structures are included to demonstrate the utility and application of the present disclosure.

Microelectronic devices are being continually improved to reliably operate with smaller feature sizes. Fabricating such microelectronic devices satisfying area scaling and reliability requirements is challenging. Certain metal-oxide-semiconductor (MOS) transistors includes features for supporting high voltage operations—e.g., with a voltage applied to their drain (or drain structure) of about 20V, 30V, 40V, or even greater. Such MOS transistors may include drain diffusion profiles (or drain junction profiles) devised to support the high voltages applied to the drain—e.g., having an extended portion to distribute the voltage drop across wider areas. Accordingly, such MOS transistors can be referred to as drain-extended MOS transistors, for example drain-extended n-channel MOS (DENMOS) transistors, drain-extended p-channel MOS (DEPMOS) transistors, laterally-diffused MOS (LDMOS) transistors, as well as groups of DENMOS and DEPMOS transistors (which can be referred to as complimentary drain-extended MOS or DECMOS transistors).

Described examples include doped regions of various semiconductor structures which can be characterized as p-doped and/or n-doped regions or portions, and include regions that have majority dopants of a particular type, such as n-type dopants (providing electrons as charge carriers) or p-type dopants (providing holes as charge carriers). For the purposes of this description, doping of the first type can be n-type doping (n-doped, first conductivity type) and doping of the second type can be p-type doping (p-doped, second conductivity type).

Disclosed examples include a microelectronic device with an improved process flow for a power isolation (PI) region and a shallow trench isolation (STI) region of a LDMOS transistor 101. Although the LDMOS transistor 101 described herein is an n-channel type (or an n-channel LDMOS), a p-channel type LDMOS transistor (or a p-channel LDMOS) can be formed in accordance with the present disclosure when n-doped regions are substituted by p-doped regions, and p-doped regions are substituted by n-doped regions.

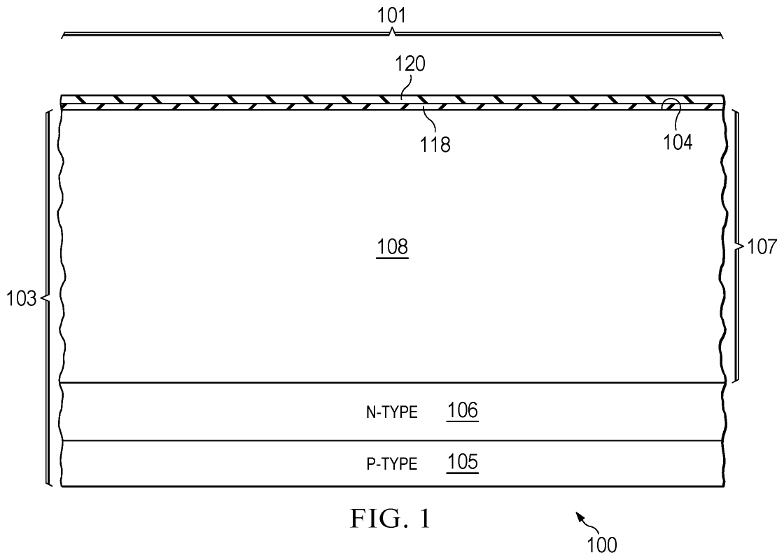

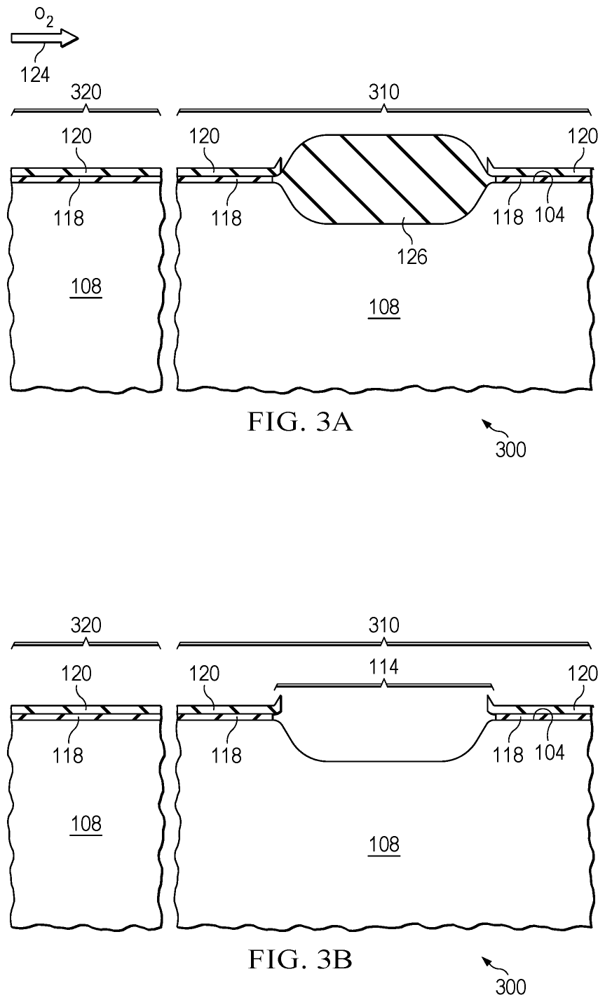

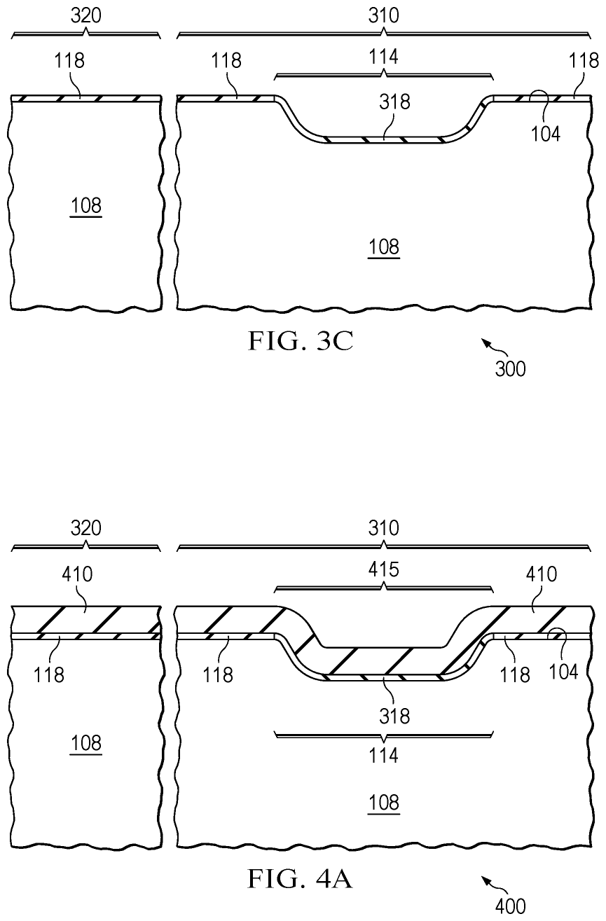

A first example process flow for forming a microelectronic device including a LDMOS transistor is described with reference FIGS. 1, 2 and FIGS. 4A through 4E. A second example process flow for forming a microelectronic device including a LDMOS transistor is described with reference FIGS. 1, 2 and FIGS. 5A through 5F. The first or second process flows may further include certain intervening processes involving local oxidation of silicon (LOCOS), as described herein with reference to FIGS. 3A through 3C.

The first example process flow uses a self-aligned underfill process, in which underfill is used to block the removal of an STI nitride hard mask from the PI region during STI processing. The first example process flow may thus facilitate forming the PI region with a fewer number of process steps (e.g., a reduced number of photolithographic pattern and etch processes) used to form the PI region and the STI region, thereby providing cost savings and simplification. The first example process flow can also provide cost savings and simplification by using only a single a chemical mechanical planarization (CMP) process in forming the PI region, as opposed to using multiple CMP processes.

The second example process flow uses a thick STI hard mask for a nitride fill and repurposes the same as a hard mask in forming the STI region as well. The second example process flow can provide cost savings and simplification by reducing the number of overall process steps (e.g., a reduced number of photolithographic pattern and etch processes) used to form the PI region and an STI region of a transistor.

FIG. 1 shows a cross section of a microelectronic device generally referred to as device 100 at an early stage of manufacturing, in which a base wafer 105 includes a semiconductor material layer, referred to herein as a substrate 103. The substrate 103 has a top surface 104. The base wafer 105 can include, for example, an epitaxial layer over a bulk semiconductor wafer, or may be part of a silicon-on-insulator (SOI) wafer, or other structure(s) suitable for forming microelectronic devices such as electronic device 400 and/or electronic device 500, described infra .

An n-type buried layer (NBL) 106 may optionally be formed over the base wafer 105. The base wafer 105 can be p-type with a dopant concentration of 1×10¹⁷ atoms/cm³ to 1×10¹⁸atoms/cm³, for example. Alternatively, the base wafer 105 can be lightly doped, with an average dopant concentration below 1×10¹⁶ atoms/cm³. The NBL 106 can be 2 microns to 10 microns thick, by way of example, and may have a dopant concentration of 1×10¹⁷ atoms/cm³ to 1×10¹⁸ atoms/cm³. In the illustrated example an epitaxial layer 107 of silicon is over the NBL 106. The epitaxial layer 107 is part of the substrate 103, and can be 2 microns to 12 microns thick, for example. The epitaxial layer 107 can be p-type, lightly doped with a dopant concentration of 1×10¹⁵ atoms/cm³ to 1×10¹⁶ atoms/cm³, by way of example. In versions of this example in which the base wafer 105 lacks the NBL 106, the epitaxial layer 107 can be directly on the base wafer 105. As will become apparent in the discussion the epitaxial layer 107 may serve as a body region 108 of the LDMOS transistor 101. The body region 108 has a first conductivity type, p-type in the current example.

A pad oxide layer 118 of silicon dioxide has been formed on the substrate 103 in an earlier process step. The pad oxide layer 118 may include silicon dioxide that is formed by a thermal oxidation process or a chemical vapor deposition (CVD) process. The pad oxide layer 118 may provide stress relief between the substrate 103 and subsequent layers. The pad oxide layer 118 can be 5 nm to 50 nm thick, by way of example. A silicon nitride layer 120 mas also been deposited on the pad oxide layer 118 in an earlier process step.

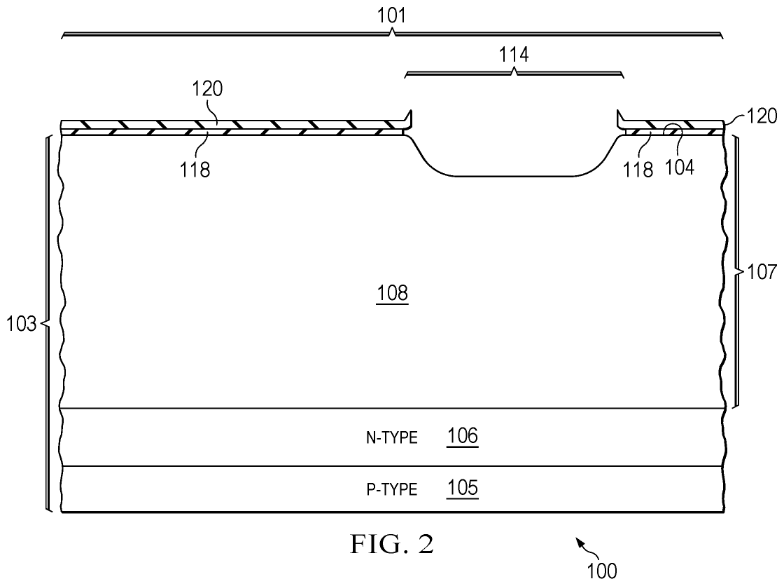

Referring to FIG. 2, a patterned photomask has been formed (not specifically shown) to define an opening corresponding to a trench 114. The photomask serves the function of masking the silicon nitride layer 120 and it may include a light sensitive organic material that is coated, exposed, and developed. One or more etch processes (e.g., plasma etch or dry etch) can be used to remove the silicon nitride layer 120 and optionally the pad oxide layer 118 in the exposed region of the photomask. In a first example a LOCOS process may be used to form the trench 114. In this example a LOCOS oxide layer (not shown) is grown by any suitable LOCOS process. The trench 114 is formed as the epitaxial layer 107 is consumed by forming the LOCOS oxide layer, and remains after the LOCOS oxide layer is removed, e.g. by HF strip. In a second example, the trench 114 may be formed by selectively removing a portion of the epitaxial layer 108 exposed by the opening in the silicon nitride layer 120 by a plasma etch. However the trench 114 is formed, structures related to it may be referred to hereinafter without implied limitation using the term “LOCOS” being formed in the PI.

FIGS. 3A through 3C are cross sections of two separate portions of a microelectronic device 300 representative of the microelectronic device 100 at a later stage of manufacturing, in which is representatively shown a PI region 310 and a STI region 320 in successive stages of formation.

FIG. 3A shows the device 300 after processing including the LOCOS option, using LOCOS furnace oxidation 124 to form a dielectric layer 126, including within the trench 114. Any suitable LOCOS process may be used, e.g. steam oxidation. The dielectric layer 126 can be formed with a thickness that overfills the PI trench 114. In various examples the dielectric layer 126 has a thickness in a range between 50 nm and 150 nm. Dielectric layers such as the dielectric layer 126 derived from LOCOS-type processing may have a tapered edge, become thinner near their perimeter and end in a “bird's beak” where the field relief dielectric layer 126 meets the epitaxial layer 107. At the stage of formation shown in FIG. 3A, the STI region 320 has yet to have an STI trench formed therein, and the pad oxide layer 118 is formed on the top surface 104 and the silicon nitride layer 120 is located on the second pad oxide layer 118.

At the stage of formation shown in FIG. 3B, the dielectric layer 126 has been removed, such as by HF strip, leaving the unfilled PI trench 114. The STI region 320 has yet to have an STI trench formed therein, and a pad oxide layer 118 remains on the top surface 104 and a second silicon nitride layer 120 remains on the second pad oxide layer 118. In examples in which the PI trench 114 is formed by removing a portion of the epitaxial layer 108 by dry etch, the bird's beak and other artifacts of LOCOS formation may not be present. If a dielectric layer 126 is formed within the PI trench 114 at the PI region 310, as shown in FIG. 3A, then the dielectric layer 126 can be removed from the PI trench 114.

Referring to FIG. 3C, an in-situ steam-generated (ISSG) oxide liner layer 318 is formed within the PI trench 114 and, thereafter, a nitride strip is used to remove the silicon nitride layer 120, as shown.

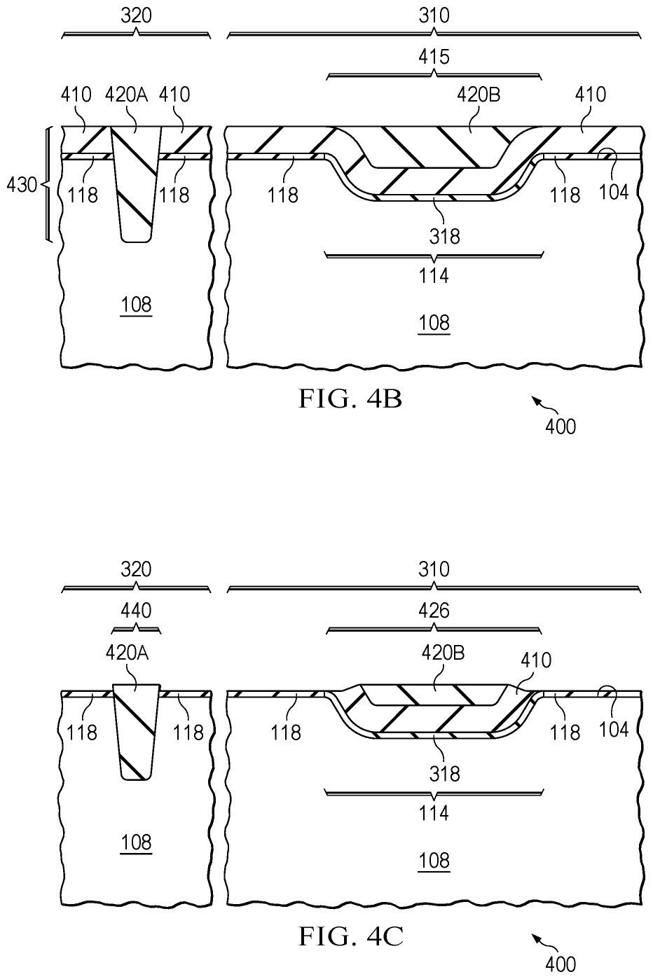

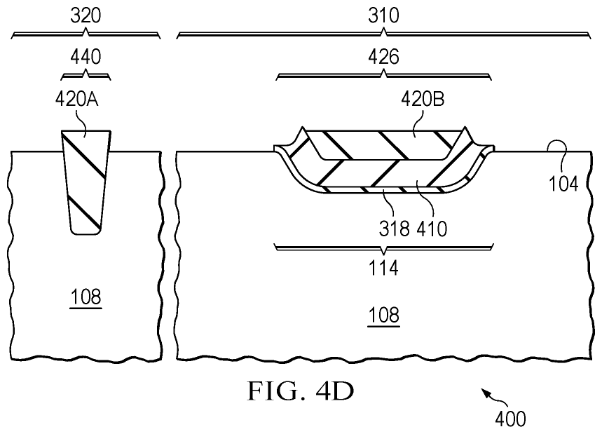

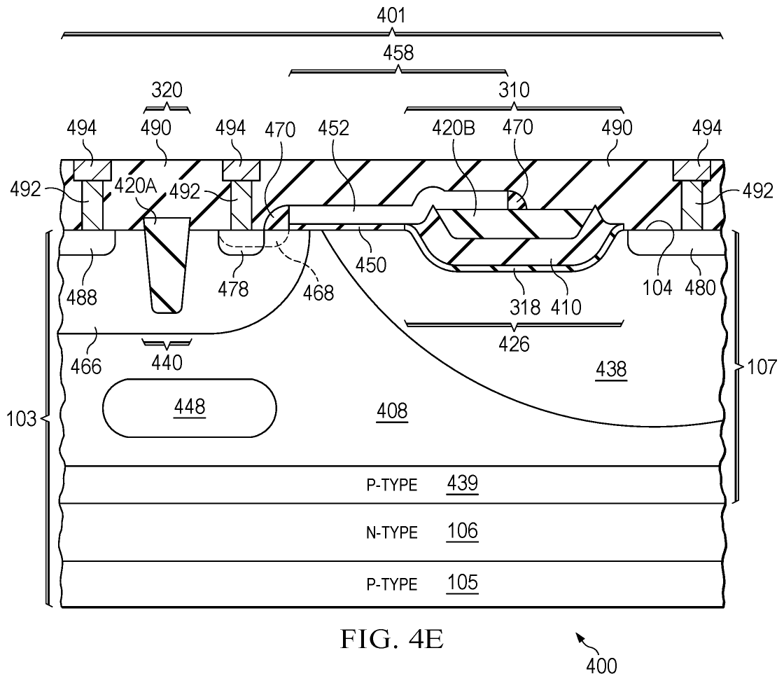

FIGS. 4A through 4C are cross sections of two separate portions of a microelectronic device 400 formed in a first example process flow starting with the device 300 as shown in FIG. 3C. The PI region 310 and an the STI region 320 are shown in successive stages of formation using a self-aligned underfill process. Referring to FIG. 4A, a silicon nitride layer 410 is formed on oxide layers 118 and 318, including within the PI trench 114 shown in FIG. 3C. The formation of the nitride layer 410 within and around the PI trench 114 results in the formation of a recess having dimensions generally conforming to the underlying PI trench 114, such that the recess is referred to herein as a projected trench 415. The silicon nitride layer 410 can be formed with a thickness that is less than the depth of the PI trench 114, such that the silicon nitride layer 410 does not completely fill the PI trench 114, and such that a top surface of the portion of the silicon nitride layer 410 at the bottom of the projected trench 415 is not coplanar with the top surface of the pad oxide layer 118 over the top surface 104.

FIG. 4B shows the PI region 310 and the STI region 320 of the microelectronic device 400 after formation of an STI trench 430. The STI trench 430 extends through respective portions of the silicon nitride layer 410, the pad oxide layer 118, and into the body region 108. A precursor dielectric layer (not explicitly shown) has been formed and partially removed, e.g. by CMP, to produce a fill dielectric 420A within the STI trench 430 and a fill dielectric 420B within the projected trench 415. To prepare underlying surfaces prior to forming the dielectric layer from which the fill dielectric 420A and 420B are formed, a photomask can be formed (not specifically shown) that includes a light sensitive organic material that is coated, exposed, and developed. The STI trench 430 itself can be formed using one or more etch processes (e.g., a plasma etch or a dry etch) that selectively removes portions of the silicon nitride layer 410 and the pad oxide layer 118 in an exposed region of the photomask. The STI trench 430, once formed, can be subsequently filled by the precursor dielectric layer.

The precursor dielectric layer is formed on the silicon nitride layer 410, within the STI trench 430 in the STI region 320, and within the projected trench 415 in the PI region 310. The dielectric layer is formed with sufficient thickness to fill the area within the projected trench 415 in the PI region 310 and the area within the STI trench 430 in the STI region 320. The dielectric layer can contain any suitable dielectric material, such as high-density plasma (HDP) oxide. The dielectric layer is then partially removed, or planarized by chemical mechanical planarization (CMP) to provide the planarized top surface representatively shown in FIG. 4B and to form the fill dielectric 420A in the STI trench 430 and the fill dielectric 420B in the projected trench 415.

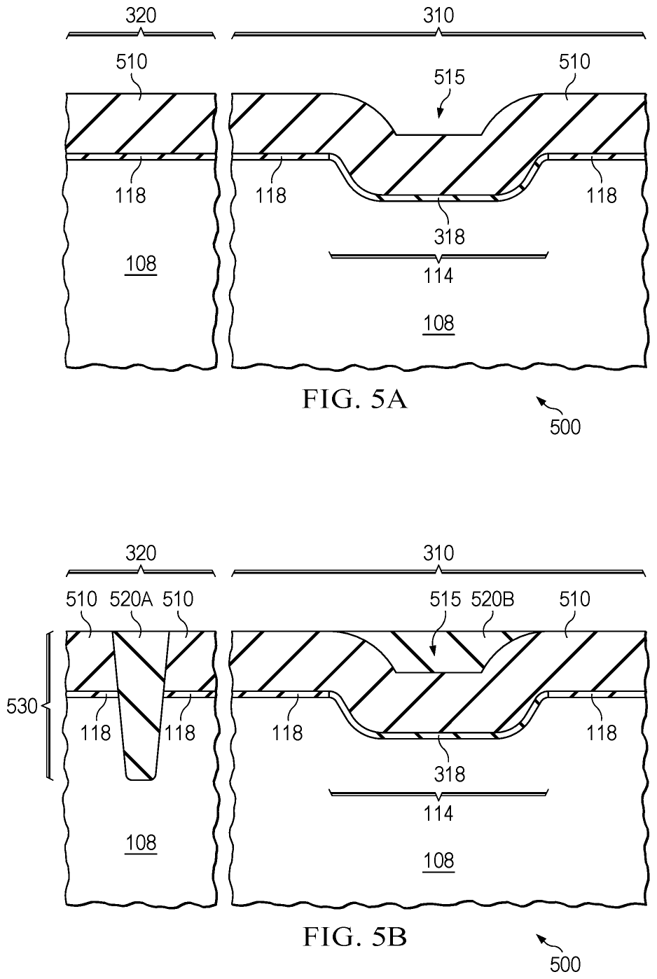

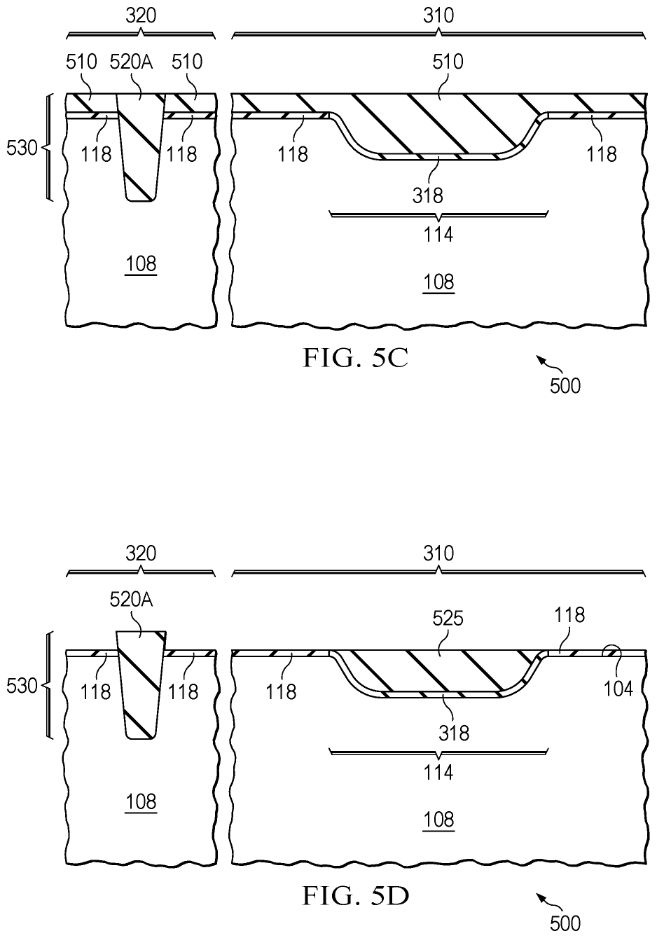

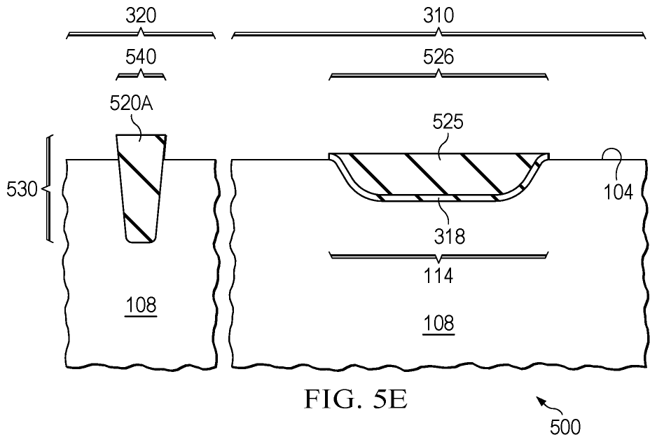

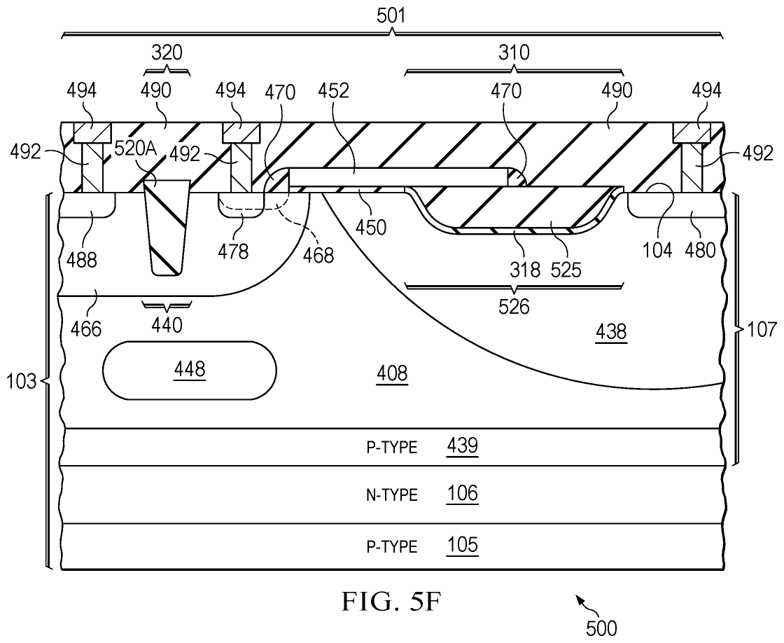

FIG. 4C shows the PI region 310 and the STI region 320 of the microelectronic device 400 after formation of a PI structure 426 within the PI region 310 and an STI structure 440 within the STI region 320. The structures 426 and 440 can be formed, for example, using a wet clean to selectively remove most or all of the silicon nitride layer 410 over the top surface 104. The presence of the fill dielectric 420B within the PI trench 114 allows a portion of the silicon nitride layer 410 to remain between the fill dielectric 420B and the oxide liner 318. As shown in FIG. 4C, a remaining portion of the silicon nitride layer 410 forms sidewalls above the PI trench 114 which can extend above the pad oxide layer 118. The sidewalls can also define a bowl-like structure that surrounds the portion of the fill dielectric 420B above the PI trench 114. (See FIG. 5A, infra.)

The removal of the silicon nitride layer 410 in the STI region 320 results in an STI structure 440 that has a step height extending above the outer surface of the pad oxide layer 118. Forming STI structure 440 with a minimum step height above the outer surface of the pad oxide layer 118 may minimize the risk of the top surface of fill dielectric 420A receding into the trench 430 during subsequent process steps, which may benefit operation and reliability of the device 400.

As a result of the example processing described with reference to FIG. 4C, the PI structure 426 and the STI structure 440 can each have a respective planar top surface that is formed by the fill dielectric 420A and the fill dielectric 420B and that has the same step height relative to parallel a planar top surface of the pad oxide layer 118.

FIG. 4D shows the PI region 310 and the STI region 320 of the microelectronic device 400, after the removal of the pad oxide layer 118 (e.g., using a plasma etch process). The presence of the silicon nitride layer 410 within the PI trench 114 (e.g. FIG. 2) can at least partially protect the oxide liner layer 318 from being removed in the same process. As shown in FIG. 4D, the removal of the pad oxide layer 118 can also result in removal of relatively small portions of the fill dielectric 420A and the fill dielectric 420B, such that the illustrated sidewalls of the silicon nitride layer 410 may extend slightly above the planar outer surface of the fill dielectric 420B of the PI structure 426.

It can be advantageous in certain applications to have the remaining portion of the silicon nitride layer 410 sufficiently cover oxide liner layer 318. For example, the illustrated configuration may facilitate omitting certain additional process steps (e.g., replacing removed oxide and subsequently performing a reverse LOCOS pattern, etch, etc.) when forming the PI region 310. In addition, the example process flow described herein with reference to FIGS. 4A through 4D may provide cost savings and simplification by using only a single CMP step (described with reference to FIG. 4B) in forming the PI structure 426 within PI region 310, as opposed to other process flows requiring more than one CMP step.

FIG. 4E shows the microelectronic device 400 after the completion of additional processing steps to complete an LDMOS transistor 401. At any suitable point in the processing, a source region 478, a drain region 480, and a back gate region 488 of the LDMOS transistor 401 is formed at respective locations within the substrate 103, such that each has a respective outer surface coplanar with the top surface 104 of the substrate 103. A p-type well region 466, a p-type shallow well region 448, and a drain drift region 438 can be formed in respective portions of the body region 408. An optional p-type buried layer (PBL) 439 can also be formed in the body region 408 using a high energy p-type implant (not specifically shown) to add p-type doping to the epitaxial layer 107. The high energy p-type implant can comprise boron at a dose from 1×10¹² cm⁻² to 1×10¹³ cm⁻² at an energy of 400 keV to 3 mega-electron volts (MeV). Indium may also be used as the implant species. For low voltage (e.g., 20 V) versions of the LDMOS transistor 401, the high energy p-type implant can be a blanket implant, while for higher voltage (e.g., >30 V) versions of the LDMOS transistor 401, the high energy p-type implant can be a masked implant to allow selective placement. Optionally, an n-type dopant such as arsenic or antimony can also be added to a source side of the LDMOS transistor 401 to form an n-type dwell region 468.

A pre-metal dielectric (PMD) layer 490 is formed over the top surface 104 of the substrate 103 and contacts 492 through the PMD layer 490 can be formed. The contacts 492 can be formed, for example, by patterning and etching holes through the PMD layer 490. Contacts 492 can be filled by sputtering titanium to form a titanium adhesion layer, followed by forming a titanium nitride diffusion barrier. A tungsten core may then be formed by a process using tungsten hexafluoride (WF₆). The tungsten, titanium nitride, and titanium are subsequently removed from a top surface of the PMD layer 490 by a plasma etch process, a tungsten CMP process, or a combination of both, leaving the contacts 492 extending to the top surface of the PMD layer 490.

Interconnects 494 can be formed on the contacts 492. The contacts 492 and interconnects 494 can provide electrical contact between the LDMOS transistor 401 and other components of the microelectronic device 400, e.g. an integrated circuit. In versions of this example in which the interconnects 494 have an etched aluminum structure, for example, the interconnects 494 can be formed by depositing an adhesion layer, an aluminum layer, and an anti-reflection layer, and forming an etch mask (not explicitly shown) followed by a reactive-ion etching (RIE) process to etch the anti-reflection layer, the aluminum layer, and the adhesion layer where exposed by the etch mask, and subsequently removing the etch mask.

In versions of this example in which the interconnects 494 have a damascene structure, the processing may include forming an inter-metal dielectric (IMD) layer (not specifically shown) on the PMD layer 490, and etching interconnect trenches through the IMD layer to expose the contacts 492. The interconnect trenches can be filled with a barrier liner and copper. The copper and barrier liner can be subsequently removed from a top surface of the IMD layer by a copper CMP process.

A gate polysilicon layer 452 can be formed on respective portions of a gate dielectric layer 450 and PI structure 426. The polysilicon layer 452 can be used to form a gate electrode 458 having later surfaces in contact with sidewalls 470. The sidewalls 470 can be formed, for example, by a blanket formation with one or more conformal layers of a dielectric material over the substrate 103 and over the gate electrode 458. The dielectric material is subsequently removed from horizontal surfaces, that is, surfaces generally parallel to the top surface 104 of the substrate 103, by an anisotropic etch process such as a RIE process, leaving the dielectric material on the lateral surfaces of the gate electrode 458 as the sidewall 470. The sidewall 470 may include dielectric materials such as silicon dioxide, silicon nitride, or both. The sidewall 470 may extend 50 nanometers to 200 nanometers from the lateral edge of the gate electrode 458.

In another example, FIGS. 5A through 5F are cross sections of two separate portions of a microelectronic device 500 formed in a first example process flow starting with the device 300 as shown in FIG. 3C. The PI region 310 and the STI region 320 are shown in successive stages of formation in a process flow that uses a thicker silicon nitride hard mask relative to that used in FIGS. 4A through 4D. In FIGS. 5A through 5F, like numbers refer to like features described previously.

Referring to FIG. 5A, a silicon nitride layer 510 is formed on the oxide layers 118 and 318. The silicon nitride layer 510 has a thickness sufficient to completely fill the PI trench 114 in the PI region 310, with sufficient overfill to achieve a certain step height for a later-formed STI structure. (See FIGS. 5C-5F, infra.) The silicon nitride layer 510 fills the PI trench 114 at least partially conformally, forming a projected trench 515.

FIG. 5B shows the PI region 310 and the STI region 320 of microelectronic device 500, after formation of an STI trench 530 extending through respective portions of the silicon nitride layer 510 and the pad oxide layer 118, and into the body region 108, and after the formation of a dielectric layer (not explicitly shown). To prepare underlying surfaces prior to forming the dielectric layer, a photomask can be formed (not specifically shown) that includes a light sensitive organic material that is coated, exposed, and developed. The STI trench 530 itself can be formed using one or more etch processes (e.g., a plasma etch or a dry etch) that selectively removes portions of the silicon nitride layer 510 and the pad oxide layer 118 in an exposed region of the photomask. The STI trench 530, once formed, can be subsequently filled by the dielectric layer.

The dielectric layer is formed on the silicon nitride layer 510, within the STI trench 530, and within the projected trench 515. The dielectric layer is formed with sufficient thickness to fill the projected trench 515 and the STI trench 530. The dielectric layer can contain any suitable dielectric material, such as HDP oxide.

The dielectric layer may be partially removed by planarization processing (e.g., using a nonselective CMP). In a first planarization example, the planarization processing may be controlled to end upon forming the configuration representatively shown in FIG. 5B, in which respective fill dielectric 520B and fill dielectric 520A remain within the projected trench 515 and within the STI trench 530.

Optionally, and as shown in FIG. 5C, the planarization processing may be controlled to remove the fill dielectric 520B, while leaving a step height of the fill dielectric 520A above oxide liner layer 318. Alternatively, the fill dielectric 520B may be removed, and the silicon nitride layer 510 may be thinned, by using a dry etch process that is nonelective to silicon oxide and silicon nitride. Providing a sufficient step height of the fill dielectric 520A above the top surface of the pad oxide layer 118 may minimize the risk of the top surface of the fill dielectric 520A receding into the trench 530 while being subjected to subsequent process steps, which could otherwise can degrade performance and/or reliability of the microelectronic device 500.

FIG. 5D shows the PI region 310 and the STI region 320 of the microelectronic device 500 after using a selective etch-back (e.g., a wet clean) to remove the silicon nitride layer 510 over the oxide layer 118 leaving the fill dielectric 520A and the oxide layers 118 and 318 substantially undisturbed. The selective etch-back is configured to allow a nitride fill portion 525 of the silicon nitride layer 510 to remain within the PI trench 114 of the PI region 310, such that the PI trench 114 remains filled with silicon nitride up to a plane that is coplanar with the top surface 104 of the substrate 103 or the top surface of the pad oxide layer 118.

FIG. 5E shows the PI region 310 and the STI region 320 of the microelectronic device 100, after the removal of the pad oxide layer 118 (e.g., using a plasma etch process). The removal of the pad oxide layer 118 can form a recessed bowl-shaped LOCOS structure 526 having a top surface that is nearly coplanar with the top surface 104 of the substrate 103. The LOCOS structure 526 includes the oxide liner layer 318 the nitride fill portion 525. The removal of the silicon nitride layer 510 in the STI region 320 leaves behind an STI structure 540 that has a step height extending above the top surface of the pad oxide layer 118. As stated above, forming STI structure 540 with a minimum step height above the outer surface of the pad oxide layer 118 may provide certain advantages, including minimize the risk of the fill dielectric 520A receding into the trench 530 while being subjected to subsequent process steps, which could otherwise degrade performance of the LDMOS transistor 101.

FIG. 5F shows the microelectronic device 500 after the completion of additional processing steps to complete an LDMOS transistor 501. These additional processing steps may be as described with respect to FIG. 4E, where like reference indexes in FIG. 5F refer to like features in FIG. 4E that may be formed as previously described.

Thus, the microelectronic device 500 can be formed, at least in part, using the process flow described with reference to FIGS. 1, 2, 3A, 3B, or 3C, followed by the additional processes described with reference to FIGS. 5A through 5F. Such a process flow can use a thick STI hard mask for a LOCOS nitride fill and repurposes the same as a hard mask in forming the STI region 320 as well. Among other advantages, this example process flow can provide cost savings and simplification by reducing the number of overall process steps used to form the PI region 310 and an STI region 320 of a an LDMOS transistor 101.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. To aid the Patent Office, and any readers of any patent issued on this application, in interpreting the claims appended hereto, applicant notes that there is no intention that any of the appended claims invoke 35 U.S.C. § 112(f) as it exists on the date of filing hereof unless the words “means for” or “step for” are explicitly used in the claim language.

In the foregoing descriptions, for purposes of explanation, numerous specific details are set forth to provide a thorough understanding of one or more examples. However, this disclosure can be practiced without some or all these specific details, as will be evident to one having ordinary skill in the art. In other instances, well-known process steps or structures have not been described in detail in order not to unnecessarily obscure this disclosure. In addition, while the disclosure is described in conjunction with example examples, this description is not intended to limit the disclosure to the described examples. To the contrary, the description is intended to cover alternatives, modifications, and equivalents as can be included within the spirit and scope of the disclosure as defined by the appended claims.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function can be configured (e.g., programmed and/or hardwired) at a time of manufacturing by a manufacturer to perform the function and/or can be configurable (or reconfigurable) by a user after manufacturing to perform the function and/or other additional or alternative functions. The configuring can be through firmware and/or software programming of the device, through a construction and/or layout of hardware components and interconnections of the device, or a combination thereof.

As used herein, the terms “terminal”, “node,” “interconnection,” “pin,” and “lead” are used interchangeably. Unless specifically stated to the contrary, these terms are generally used to mean an interconnection between or a terminus of a device element, a circuit element, an integrated circuit, a device, or other electronics or semiconductor component.

While certain elements of the described examples can be included in an integrated circuit and other elements can be external to the integrated circuit, in other examples, additional or fewer features can be incorporated into the integrated circuit. In addition, some or all of the features illustrated as being external to the integrated circuit can be included in the integrated circuit and/or some features illustrated as being internal to the integrated circuit can be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

It is noted that terms such as top, bottom, over, above, and under can be used in this disclosure. These terms should not be construed as limiting the position or orientation of a structure or element, but should be used to provide spatial relationship between structures or elements. The terms “lateral” and “laterally” refer to directions parallel to a plane corresponding to a surface of a layer, for example a top surface of a semiconductor substrate.

In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible within the scope of the disclosure.

What is claimed is:

1. A method of forming an integrated circuit, comprising;
forming a first trench that extends into a semiconductor substrate;
depositing a silicon nitride layer over the semiconductor substrate, the silicon nitride layer extending into the first trench;
forming a second trench that extends through the silicon nitride layer into the semiconductor substrate, the second trench spaced apart from the power isolation trench;
forming an oxide layer that fills the second trench; and
removing the silicon nitride layer outside the first trench.

2. The method as recited in claim 1, wherein the first trench is a power isolation trench and the second trench is a shallow isolation trench.

3. The method as recited in claim 1, wherein forming the first trench includes forming and removing a LOCOS oxide region that extends into the first trench.

4. The method as recited in claim 1, wherein forming the silicon nitride layer results in a projected first trench over the first trench, and the oxide layer fills the projected first trench.

5. The method as recited in claim 1, wherein a top surface of the silicon nitride layer within the first trench is below a top surface of the semiconductor substrate.

6. The method as recited in claim 1, wherein a portion of the oxide layer remains over the first trench after removing the silicon nitride layer.

7. The method as recited in claim 1, wherein a portion of the silicon nitride layer remains within the first trench after removing the silicon nitride layer, the silicon nitride layer portion having a top surface coplanar with a top surface of the semiconductor substrate.

8. The method as recited in claim 1, wherein a remaining portion of the silicon nitride layer within the first trench extends above a top surface of the semiconductor substrate after removing the silicon nitride layer outside the first trench.

9. The method as recited in claim 1, further comprising polishing the oxide layer thereby removing the oxide layer over a planar portion of the silicon nitride layer and leaving a remaining portion of the oxide layer over the first trench.

10. The method as recited in claim 9, further comprising non-selectively etching the planar portion of the silicon nitride layer and the remaining portion of the oxide layer, thereby removing the remaining portion of the oxide layer.

11. The method as recited in claim 1, wherein the oxide layer that fills the shallow isolation trench is a field relief dielectric layer of a transistor.

12. A semiconductor device, comprising:
a semiconductor layer over a substrate, the semiconductor layer including a body region having a first conductivity type and a drain drift region having a different second conductivity type;
a first trench extending into the body region, the first trench being at least partially filled by a dielectric material; and
a second trench extending into the drain drift region, the second trench being at least partially filled by a silicon nitride layer, the silicon nitride layer extending above a top surface of the drain drift region, the silicon nitride layer forming a projected trench above the second trench, the projected trench at least partially filled with the dielectric material.

13. The semiconductor device of claim 12, wherein the second trench is wider than the first trench.

14. The semiconductor device of claim 12, wherein an oxide layer is between the silicon nitride layer and a top surface of the second trench extending into the well region.

15. The semiconductor device of claim 12, wherein a portion of the drain drift region has a top surface that is coplanar with a top surface of a portion of the well region.

16. The semiconductor device of claim 12, further comprising a gate of the transistor having a portion thereof on the dielectric material that fills the projected trench above the second trench.

17. A semiconductor device, comprising:
a semiconductor material of a substrate, the semiconductor material including a body region having a first conductivity type and a drain drift region having a second conductivity type;
a first trench extending into the body region, the first trench being at least partially filled by a dielectric material; and
a second trench extending into the drain drift region, the second trench being at least partially filled by a silicon nitride layer, the silicon nitride layer having a top surface that is coplanar with a top surface of the drain drift region.

18. The semiconductor device of claim 17, wherein the second trench is wider than the first trench and an oxide layer is between the silicon nitride layer and a top surface of the second trench extending into the well region.

19. The semiconductor device of claim 17, wherein a portion of the drain drift region has a top surface that is coplanar with a top surface of a portion of the well region.

20. The semiconductor device of claim 17, further comprising a gate of the transistor having a portion thereof on the silicon nitride layer above the second trench.
